(19) United States
(12) Patent Application Publication
(10) Pub. No.: US 2006/0232922 A1
(43) Pub. Date: Oct. 19, 2006

(54) Portable digital storage device

(76) Inventor: Jiun-Hong Tong, Taipei (TW)

Correspondence Address: LIN & ASSOCIATES INTELLECTUAL PROPERTY, P.O. BOX 2339, SARATOGA, CA, 95070-0339, US

(21) Appl. No.: 11/106,888

(22) Filed: Apr. 15, 2005

(51) Int. Cl. H05K 5/00

(52) U.S. Cl. 361/685

(57) ABSTRACT

A portable digital storage device is provided. The portable digital storage device is basically housed in a quadrangular body having an LCD screen and functional buttons on front surface, a power switch and a cable connector on top surface, and a pair of memory card slots on bottom surface, and an enclosure inside the quadrangular body with connector socket fixed on one end for receiving a disk drive. A special disk adaptor is provided for mounting slim disk drive. The portable digital storage device can be connected to a host computer through a connection cable for data transfer between the two. The portable digital storage device can also be operated alone with a memory card inserted for playing audio video. When connected, the portable digital storage device can also double up as a card reader/writer for a computer system.

### BACKGROUND OF THE INVENTION

1. Field of the Invention

The present invention relates to a portable digital storage device, and in particular to a portable digital storage device employing unique disk interface structure that enables easy replacement of disk drives, and enhances data portability.

2. The Related Art

Basically, there are two types of data storage devices available. The first one needs to be installed in one of the expansion slots of a personal computer, and the second one is a portable device that needs to be connected to the computer by means of a connection cable. The conventional data disk drive only allows the transfer of data files between the computer and the data storage device.

With the proliferation of digital devices and personal computers, a new generation of digital storage devices has been developed by incorporating memory card slots and audio/video features. This portable digital storage device can play audio video, store data, and act as a memory card reader with HUB.

The conventional digital storage device comes with one type of internal hard disk, so the hard disk capacity of the digital storage device cannot be tailored to meet various user requirements. In addition, when a problem occurs in the internal hard disk, since the disk drive is fixed, the circuit board has to be unscrewed and the circuit board has to be removed prior to unplugging the disk drive, for which users lacking technical skills are unable to handle.

To obviate the above-mentioned problems, the present invention intends to provide a portable digital storage device that enables easy replacement of disk drive, and enhances data portability.

### SUMMARY OF THE INVENTION

The primary object of the present invention is to provide a portable digital storage device with a unique disk interface structure that enables easy replacement of the removable disk and increases functionality of the conventional digital storage device.

The secondary object of the invention is to provide a portable digital storage device that can support different removable disks having different capacities.

In accordance with the invention, the portable digital storage device is basically housed in a quadrangular body having an LCD screen and functional buttons on the front surface, and a power switch and a cable connector on the top surface, and a pair of memory card slots on the bottom surface, and an enclosure inside the quadrangular body with connector socket fixed on one end for receiving a disk drive.

In accordance with the present invention, the present design allows for different hard disk configurations. A slim disk drive may also be used by employing a special disk adaptor, which has the slim disk drive coupled onto the disk adaptor before the adaptor is plugged into the connector socket. In one sense, the removable disk is piggybacked onto the special disk adaptor. Supposedly, many other removable disks can also be used for configuring the portable digital storage device, as long as the combined thickness of the special disk adaptor and the disk drive can fit into the space of the enclosure.

In accordance with the present invention, the removable disk is horizontally placed in the enclosure space through an opening on the backside of the quadrangular body, and the opening is normally closed by a cover plate.

In accordance with the present invention, the portable digital storage device is connected to a host computer by means of a connection cable to allow data originally stored in the computer to be successfully transferred to the portable digital storage device, or vice versa.

In accordance with the present invention, if there is a memory card in the memory card slot, the portable digital storage device can be activated without connection to the host computer. The standard features of the portable digital storage device include copying data from the portable digital storage device to the memory card, or vice versa; playing audio video with the functional buttons, and viewing pictures through the LCD screen.

The present design offers several unique features: (1) fast and easy replacement of the removable disk, without unscrewing and removing of the circuit board; (2) compatibility with all standard disk drives through the use of a special disk adaptor that is to be plugged into the connector socket of the portable digital storage device; (3) ease of increase of hard disk capacity with different configurations; and (4) capability to support large capacity disk drive, making it possible to copy entire hard disk in backup and restoration procedures.

The present invention will become more obvious from the following description when taken in connection with the accompanying drawings, which show, for purposes of illustration only, a preferred embodiment in accordance with the present invention.

### BRIEF DESCRIPTION OF THE DRAWINGS

FIG. 1 is an exploded view of one preferred embodiment of the present invention;

FIG. 2 is another exploded view of another preferred embodiment, showing the hard disk and the special disk adaptor;

FIG. 3 is an exploded view of the disk interface using a special disk adaptor;

FIG. 4 is top view of the second embodiment of the invention after the disk drive and disk adaptor are installed in the main body;

FIG. 5 is back view of the portable digital storage device; and

FIG. 6 is front view of the portable digital storage device.

### DETAILED DESCRIPTION OF THE PREFERRED EMBODIMENT

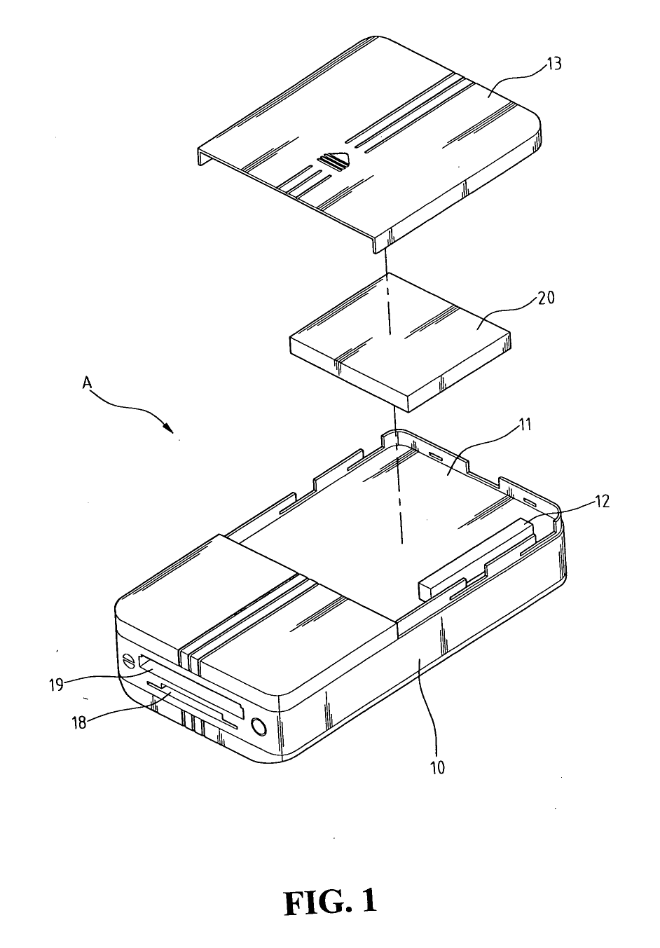

Referring to FIGS. 1, 5, and 6, a portable digital storage device (A) constructed in accordance with the present invention includes a quadrangular body 10, an removable disk 20, a special disk adaptor 30, a built-in battery (not shown), a main circuit board (not shown) and a cover plate 13.

The quadrangular body 10 of the portable digital storage device (A) is formed with an LCD screen 14, a scroll button and functional buttons 15 on the front surface, a power switch 16 and a cable connector 17 on the top surface, and a pair of memory card slots 18, 19 on the bottom surface. The quadrangular body 10 has internal space carved out on the backside to form an enclosure 11, in which a connector socket 12 is fixed on one end for receiving a disk drive 20.

After the removable disk 20 is placed in the enclosure 11 horizontally, a cover plate 13 is placed over the enclosure opening 11 to protect the removable disk 20 from the outside environment.

In one preferred embodiment of the invention, a regular-size 1.8-inch disk drive 20 is included in the device configuration. The connector (not shown) at the back of the disk drive is directly plugged into corresponding connector socket 12, and the disk drive 20 is placed in the enclosure 11 in horizontal position.

The DIP connector and corresponding connector socket 12 used in the first preferred embodiment are hard disk interface fully compliant with standard I/O specifications for popular disk drives.

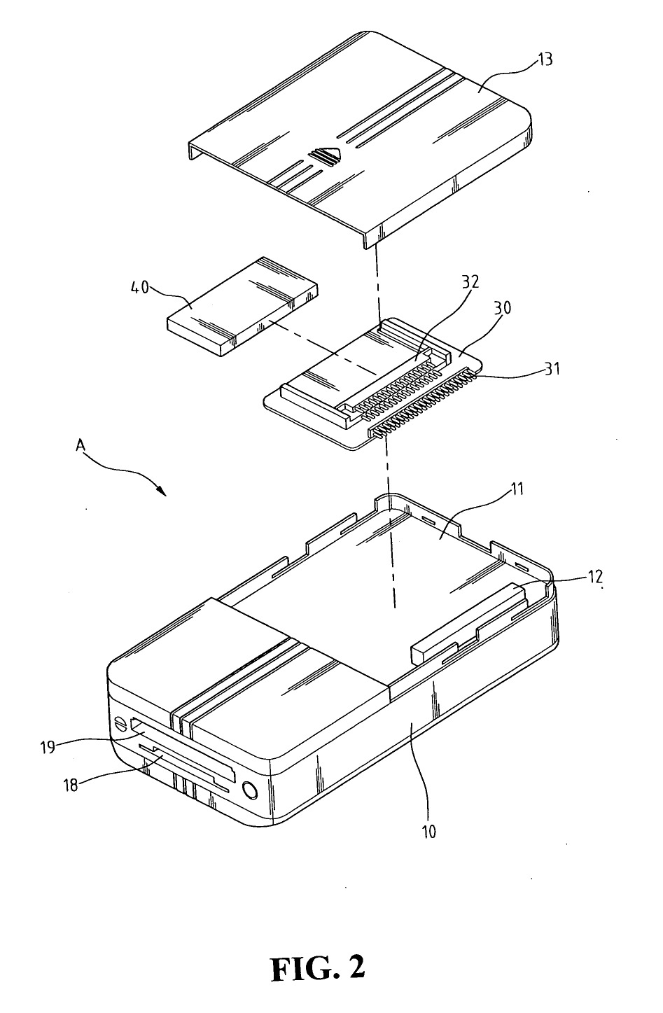

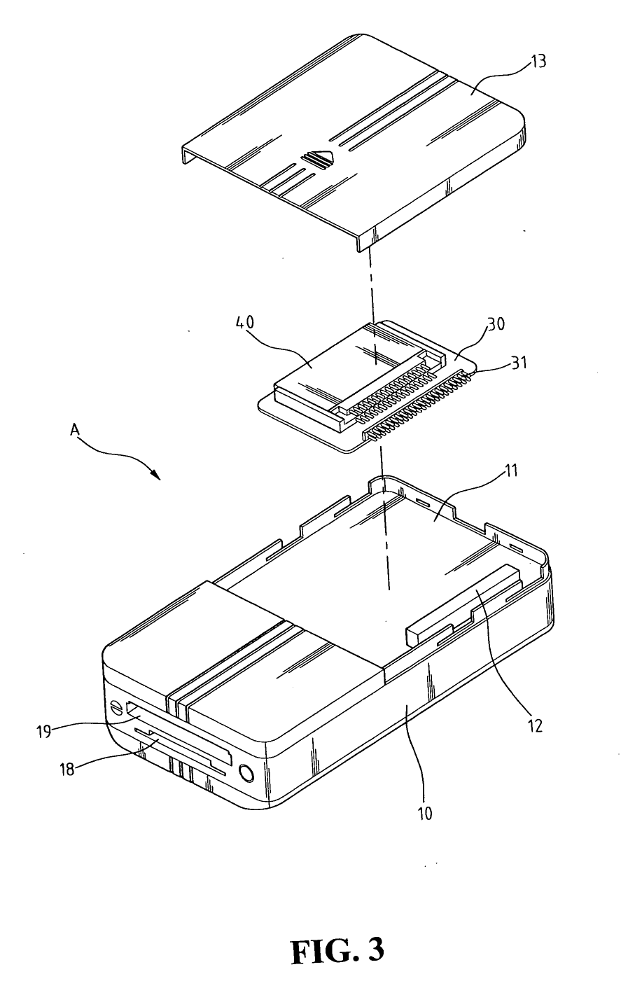

Referring to FIG. 2, the portable digital storage device is provided with a special disk adaptor 30 for mounting slim disk drives. In another preferred embodiment of the invention, the 1-inch disk drive 40 needs to be coupled onto the disk adaptor 30, before plugging in the disk drive 40, as shown in FIGS. 2-4, through a second DIP connector 31 on the disk adaptor 30 and a first connector socket 12 fixed in the enclosure 11 of the quadrangular body 10 to finish the disk mounting.

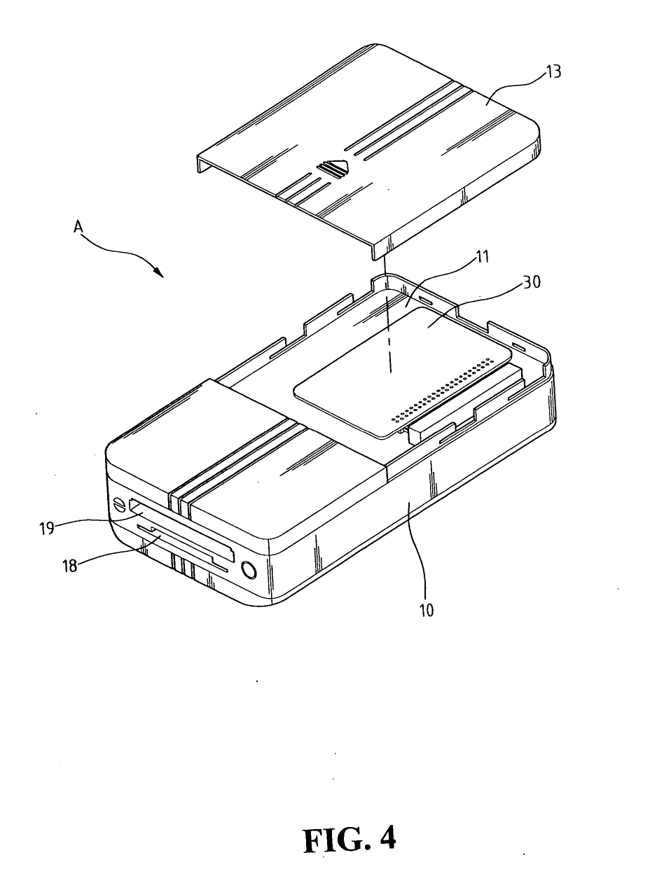

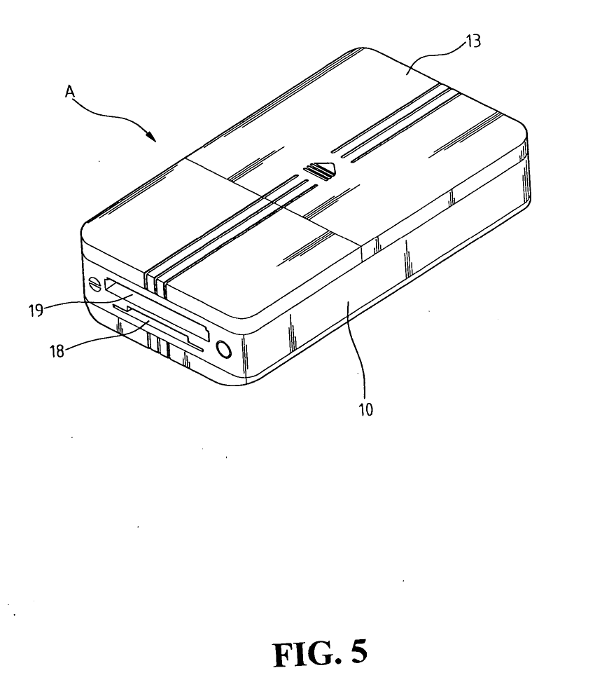

To mount a slim disk drive 40, such as 1-inch disk drive, onto the portable digital storage device, the DIP connector (not shown) at the back of the disk drive 40 is first fitted into second connector socket (not shown) on board the special disk adaptor 30, and then the disk adaptor 30 is turned over with the underside of the disk adaptor 30 facing the outside, and then the first DIP connector 31 on board the disk adaptor 30 is fitted into the first connector socket 12 as shown in FIG. 4, and then the cover plate 13 is slid into place to close the enclosure opening 11 as shown in FIG. 5.

The first and second DIP connectors and corresponding connector sockets used in the second preferred embodiment are hard disk interface fully compliant with standard I/O specifications for personal computer disk drives.

Besides 1-inch and 1.8-inch disk drives, other types of disk drives may also be configured onto the portable digital storage device with a matching disk adaptor. Many different configurations are possible as long as the dimensions of the disk drive and the special disk adaptor can fit into the enclosure space 11 for secure mounting.

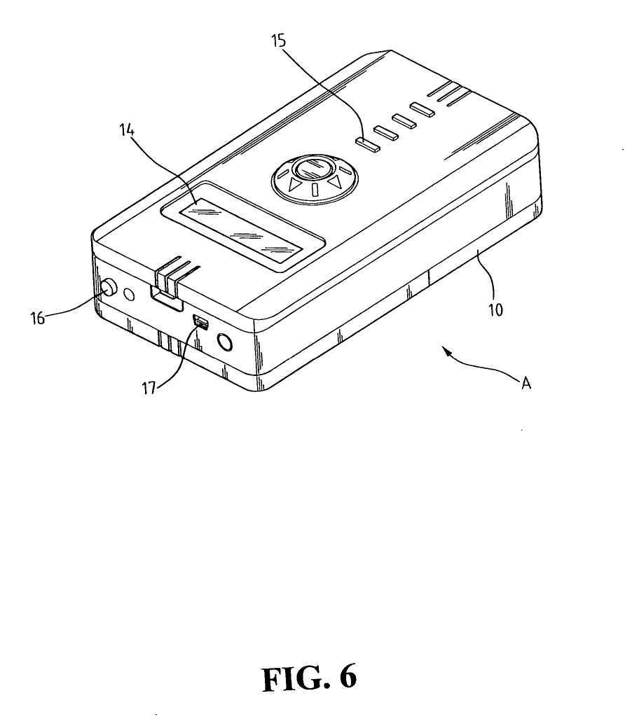

Referring to FIG. 6, the portable digital storage device has a cable connector 17, preferably USB port, that allows the digital storage device to be connected to a host computer (not shown) through a connection cable (not shown), so that data originally stored in the computer can be transferred to the removable disk 20/40 in the portable digital storage device, or vice versa.

The portable digital storage device also has a pair of memory card slots 18, 19 which allows at least two types of flash memory cards with different specifications to be used on the portable device. Data can be transferred either from the removable disk to the memory card or from the memory card to the removable disk under the control of user commands. Such operation can be performed on any memory card, plugged into the machine, including compact flash (CF), MicroDrive, memory stick (MS), memory stick pro (MS-PRO), MMC, secure digital (SD) and SmartMedia SM.

Through the LCD screen 14, functional buttons and scroll buttons 15 on the front panel, the device user is able to pick out one file from downloaded music files for playing audio video, similar to a MP3 device, or else to select a picture file for screen viewing.

When connected with the host computer, the portable digital storage device can double up as a card reader/writer.

Although the present invention has been described with reference to the preferred embodiments thereof, it is within the scope of the invention to make such variations and modifications as would be apparent to a person having ordinary skill in this field.

What is claimed is:

1. A portable digital storage device comprising:
a quadrangular body having an LCD screen and functional buttons on front surface, and a power switch and a cable connector on top surface, and a pair of memory card slots on bottom surface; and an enclosure inside the quadrangular body with connector socket fixed on one end for mounting a disk; and
a cover plate for protecting the disk.

2. The portable digital storage device as claimed in claim 1, wherein the connector socket is hard disk interface compliant with standard I/O specifications for personal computer disk drives.

3. The portable digital storage device as claimed in claim 1, wherein the cable connector is compliant with USB specifications.

4. The portable digital storage device as claimed in claim 1, wherein the pair of memory card slots supports compact flash (CF), MicroDrive, memory stick (MS), memory stick pro (MS-PRO), MMC, secure digital (SD) and SmartMedia SM.

5. A portable digital storage device comprising:
a quadrangular body having an LCD screen and functional buttons on front surface, and a power switch and a cable connector on top surface, and a pair of memory card slots on bottom surface, and an enclosure inside the quadrangular body with a first connector socket fixed on one end for mounting a disk;
a special disk adaptor having a second connector socket for receiving slim disk and a first DIP connector for plugging into first connector socket fixed in the enclosure of the quadrangular body; and
a cover plate for protecting the disk.

6. The portable digital storage device as claimed in claim 5, wherein the first and second DIP connectors and corresponding connector sockets are hard disk interface compliant with standard I/O specifications for personal computer disk drives.

7. The portable digital storage device as claimed in claim 5, wherein the cable connector is compliant with USB specifications.

8. The portable digital storage device as claimed in claim 5, wherein the pair of memory card slots supports compact flash (CF), MircoDrive, memory stick (MS), memory stick pro (MS-PRO), MMC, secure digital (SD) and SmartMedia SM.
